(19) United States
(12) Patent Application Publication
(10) Pub. No.: US 2003/0089960 A1
(43) Pub. Date: May 15, 2003

(54) Asymmetric high-voltage metal-oxide-semiconductor device

(75) Inventor: Chang-Miao Liu, Taichung (TW)

Correspondence Address: LOWE HAUPTMAN GILMAN & BERNER, LLP, Suite 310, 1700 Diagonal Road, Alexandria, VA, 22314, US

(73) Assignee: UNITED MICROELECTRONICS CORP.

(21) Appl. No.: 09/986,930

(22) Filed: Nov. 13, 2001

(51) Int. Cl. H01L 21/8238; H01L 29/00; H01L 29/76; H01L 31/062

(52) U.S. Cl. 257/500; 257/288

(57) ABSTRACT

In accordance with the present invention, a structure of an asymmetric high-voltage MOS device is disclosed. The key aspect of the present invention is a high-voltage MOS device having a drift region underneath an isolation structure, wherein the high-voltage MOS device is isolated by shallow trench isolations and formed on a silicon-on-insulator (SOI) substrate. The asymmetric high-voltage MOS device comprises a substrate having an insulating layer thereon and a semiconductor layer of a first conductive type on the insulating layer. A plurality of shallow trench isolations defining an active area is formed in the semiconductor layer. A field oxide layer is formed in the active area of the semiconductor layer. A drift region of a second conductive type is formed under the field oxide layer in the semiconductor layer. A gate structure including a conductive layer and a gate dielectric layer is formed on the semiconductor layer in the active area and covers a portion of the field oxide layer. A first source and drain regions of the second conductive type having a first dopant concentration are formed opposite to each other aside of the gate structure in the semiconductor layer in the active area, wherein the first drain region is isolated from the gate structure by the field oxide layer. A second source and drain regions of the second conductive type having a second dopant concentration are formed in the first source region and the first drain region respectively, wherein the second dopant concentration is higher than the first dopant concentration.

### BACKGROUND OF THE INVENTION

1. Field of the Invention

The present invention generally relates to an asymmetric high-voltage metal-oxide-semiconductor (HV MOS) device, and more particularly to an asymmetric high-voltage double-doped-diffusion metal-oxide-semiconductor (HV DMOS) device isolated by shallow trench isolations and formed on a silicon-on-insulator (SOI) substrate to reduce the device dimension and the substrate current.

2. Description of the Prior Art

As MOS devices become much denser, channel length is also shortened such that the operating speed is increased. However, if the applied voltage to a MOS device is unchanged while the channel length is shortened, the strength of electric field is increased. Thus, as the intensity of electric field increases, electrons will have higher energies caused by accelerating in a higher electric field and electrical breakdown is likely to occur. Electrical breakdown occurs when the voltage on the drain region is so large that the electric filed across the reverse-biased drain-to-substrate junction accelerates thermally-generated electron-hole pairs at or near the junction. The accelerated electron-hole pairs have ionizing collisions with the lattice, which form a large substrate current. The large substrate current, in turn, has numerous detrimental effects on the operation of a high-voltage device. For, example, a large substrate current will cause the junction breakdown and lateral (bipolar junction transistor) BJT snapback voltage down.

MOS devices may be used in both low-voltage and high-voltage environments. High-voltage MOS devices, however, must be able to withstand significantly larger drain voltages without inducing electrical breakdown. A high junction breakdown voltage can not be obtained in the high-voltage device, generally, due to the semiconductor substrate of high concentration and the shallow source/drain region. Thus, the performance efficiency of the high-voltage device is reduced. One technique for reducing the strength of the junction electric field of a high-voltage device is to surround the drain region with a lightly-doped region of the same conductivity type. The purpose of the lightly-doped region is to absorb some of the potential of the drain region, and thereby reduce the strength of the junction electric field. However, the drawback accompanying with the lightly-doped technique is the source/drain dimension being relatively enlarged and more complicated process being proposed.

A conventional high-voltage MOS generally adopts the local oxidation (LOCOS) isolation technique. Field oxide layer isolations are formed by a thermal oxidation to obtain a high junction breakdown voltage, which causes the difficulty in scaling down the device dimension. Moreover, scaled down thermal field oxide layer isolations reduce the effective spacing separating adjacent active regions in a semiconductor device and, thereby increases the reliability problem. Therefore, a high-voltage MOS device having a high junction breakdown voltage and smaller dimension possibility and eliminating the substrate current path is highly desired.

### SUMMARY OF THE INVENTION

The present invention is directed toward an asymmetric high-voltage metal-oxide-semiconductor (MOS). The key aspect of the present invention is a high-voltage MOS device having a drift region underneath an isolation structure, wherein the high-voltage MOS device is isolated by shallow trench isolations and formed on a silicon-on-insulator (SOI) substrate. The advantage of incorporation with shallow trench isolations is that a high junction breakdown voltage is obtained without sacrificing the device dimension. Furthermore, the substrate current, which induces a junction breakdown and lateral BJT snapback voltage down, is eliminated due to the formation of the high-voltage MOS on the silicon-on-insulator substrate. Thus, the reliability issue accompanying with high-voltage MOS is improved, such that device IV curve presents a saturation region without kink.

In accordance with the present invention, in one embodiment, a structure of an asymmetric high-voltage MOS device is disclosed. The asymmetric high-voltage MOS device comprises a substrate having an insulating layer thereon and a semiconductor layer of a first conductive type on the insulating layer. The substrate can be a silicon-on-insulator (SOI) substrate, such as a substrate having P-type silicon layer on oxide layer. A plurality of shallow trench isolations defining an active area is formed in the semiconductor layer. A field oxide layer is formed in the active area of the semiconductor layer. A drift region of a second conductive type is formed under the field oxide layer in the semiconductor layer of the first conductive type, such as a N-type drift region formed under the field oxide layer in the P-type silicon layer. A gate structure including a conductive layer and a gate dielectric layer is formed on the semiconductor layer in the active area and covers a portion of the field oxide layer. A first source region of the second conductive type (such as N-type) having a first dopant concentration and a first drain region of the second conductive type (such as N-type) having the first dopant concentration are formed opposite to each other aside of the gate structure in the semiconductor layer (such as P-type silicon layer) in the active area, wherein the first drain region is isolated from the gate structure by the field oxide layer. A second source region of the second conductive type (such as N-type) having a second dopant concentration and a second drain region of the second conductive type (such as N-type) having the second dopant concentration are spaced-apart formed in the first source region and the first drain region respectively, wherein the second dopant concentration is higher than the first dopant concentration.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIGS. 1A to 1D is a schematic cross-sectional view at different stages of forming the asymmetric high-voltage MOS device in accordance with the present invention.

### DESCRIPTION OF THE PREFERRED EMBODIMENT

Some sample embodiments of the invention will now be described in greater detail. Nevertheless, it should be noted that the present invention can be practiced in a wide range of other embodiments besides those explicitly described, and the scope of the present invention is expressly not limited except as specified in the accompanying claims.

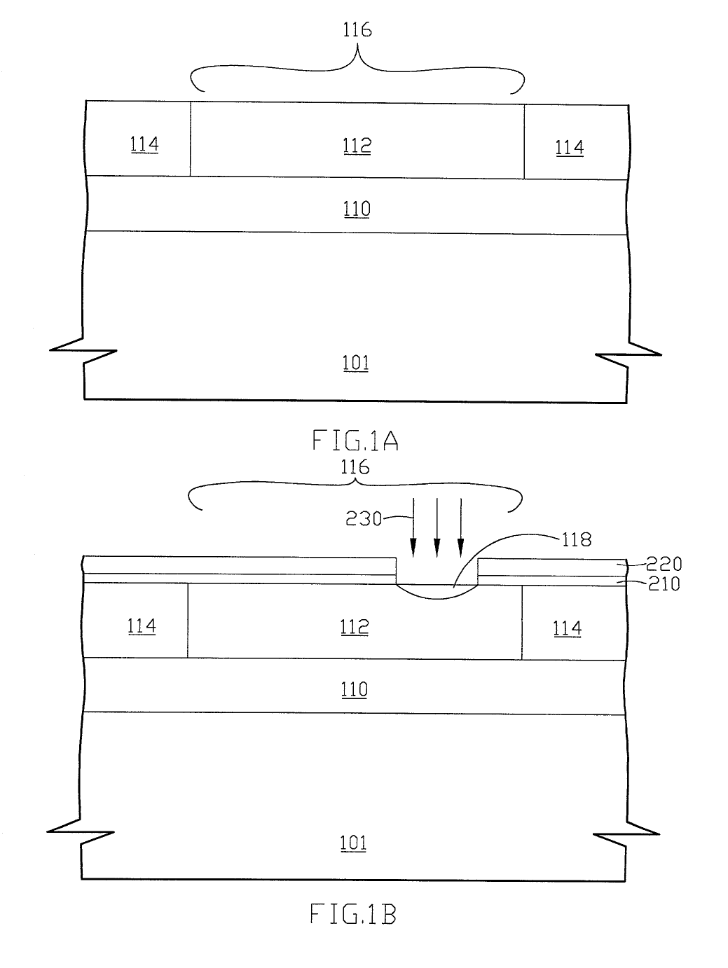

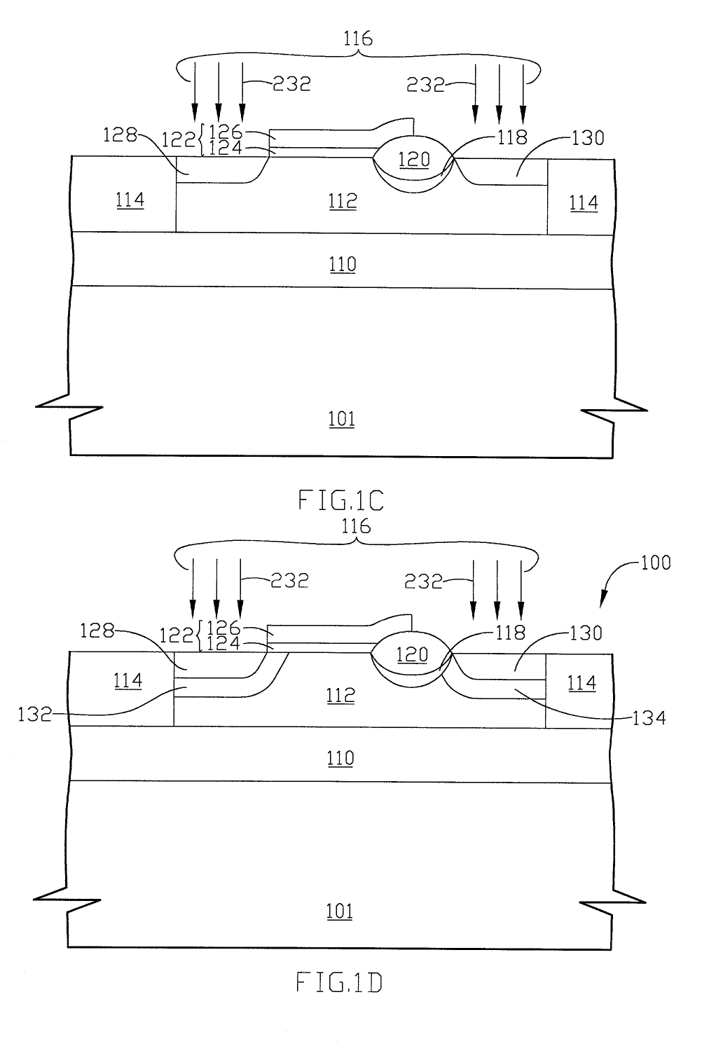

In accordance with the present invention, a structure of an asymmetric high-voltage MOS device is provided. The fabrication of the asymmetric high-voltage MOS device is depicted through FIGS. 1A to 1D according to one preferred embodiment of the present invention. As illustrated in FIG. 1D, the asymmetric high-voltage MOS device 100 comprises a substrate 101 having an insulating layer 110 thereon and a semiconductor layer 112 of a first conductive type on the insulating layer 110. A plurality of shallow trench isolations 114 defining an active area 116 is formed in the semiconductor layer 112. A field oxide layer 120 is formed in the active area 116 of the semiconductor layer 112 of the first conductive type. A drift region 118 of a second conductive type is formed under the field oxide layer 120 in the semiconductor layer 112 of the first conductive type. A gate structure 122 including a gate dielectric layer 124 and a conductive layer 126 is formed on the semiconductor layer 112 in the active area 116 and covers a portion of the field oxide layer 120. A first source region 128 of the second conductive type having a first dopant concentration and a first drain region 130 of the second conductive type having the first dopant concentration are formed opposite to each other aside of the gate structure 122 in the semiconductor layer 112 in the active area 116, wherein the first drain region 130 is isolated from the gate structure 122 by the field oxide layer 120. A second source region 132 of the second conductive type having a second dopant concentration and a second drain region 134 of the second conductive type having the second dopant concentration are spaced-apart formed in the first source region 128 and the first drain region 130 respectively, wherein the second dopant concentration is higher than the first dopant concentration.

FIGS. 1A to 1D is a schematic cross-sectional view at different stages of forming the asymmetric high-voltage MOS device according to one preferred embodiment of the present invention. Referring to FIG. 1A, the substrate 101 having the insulating layer 110 formed thereon and the semiconductor layer 112 of a first conductive type formed on the insulating layer 110 is shown. The structure of the substrate 101 can be a silicon-on-insulator (SOI) structure; that is the semiconductor layer 112 is a silicon layer of a first conductive type such as P-type silicon layer formed on the insulating layer 110 such as a silicon oxide layer. One key aspect of the present invention is that the asymmetric high-voltage MOS device is formed on the silicon-on-insulator substrate, which eliminates the substrate current path to prevent junction breakdown and lateral (bipolar junction transistor) BJT snapback voltage down. For the purpose of increasing the junction breakdown voltage between devices and reducing the device dimension, a plurality of shallow trench isolations (STI) 114 defining the active area are 116 formed in the semiconductor layer 112, such as the P-type silicon layer. In other words, the asymmetric high-voltage MOS device is formed in the active area 116 of the semiconductor layer 112 of a first conductive type such as P-type silicon layer and isolated by the shallow trench isolations 114. The formation of the shallow trench isolations is achieved by the present art including steps of transferring STI patterns into the semiconductor layer and depositing insulating material in the semiconductor layer to form the shallow trench isolations.

As shown in FIG. 1B, a pad oxide layer 210 and a silicon nitride layer 220 is subsequently formed on the semiconductor layer 112 and etched to expose a portion of the semiconductor layer 112 in the active area 116. A first ion implantation 230 is performed to form the drift region 118 of a second conductive type in the exposed portion of the semiconductor layer 112. That is, for a P-type silicon layer, an N type ion implantation is performed to form an N-type drift region in the exposed P-type silicon layer. A thermal oxidation process is performed to form the field oxide layer 120 on the drift region 118 of the semiconductor layer 112. The purpose of the field oxide layer is to prolong the voltage down between a drain and a gate of a device, in other words, to increase the junction breakdown voltage. Due to the smooth interface of the field oxide layer the junction breakdown path of a device is reduced. The gate structure 122 including a gate dielectric 124 and a conductive layer 126 is formed on the semiconductor layer 112 and covers a portion of the field oxide layer 120. The formation of the gate structure comprises steps of forming a gate dielectric layer and a conductive layer on the semiconductor layer, forming a patterned photoresist on the conductive layer which defines the gate structure, and etching the conductive layer and the gate dielectric layer to form the gate structure. The gate dielectric layer 124 and the conductive layer 126 can be a gate oxide layer and a polysilicon layer respectively.

A second ion implantation 232 is performed to form the first source region 128 of the second conductive type with a first dopant concentration and the first drain region 130 of the second conductive type with a first dopant concentration in the semiconductor layer 112 in the active area 116. A thermal drive-in step is performed to form an uniform deep doping profile of the first source region 128 and the first drain region 130, which are opposite to each other aside of the gate structure 122 in the semiconductor layer 112 in the active area 116, wherein the first drain region 130 is isolated from the gate structure 122 by the field oxide layer 120. A third ion implantation 234 is performed to form the second source region 132 of the second conductive type with a second dopant concentration and the second drain region 134 of the second conductive type with a second dopant concentration in the first source region 128 and the first drain region 130, respectively, wherein the second dopant concentration is higher than the first concentration. The lightly doped first source and drain regions 128,130 serve as high potential junction barriers and can contact the insulating layer. Thus, incorporation with shallow trench isolations, a high junction breakdown voltage is obtained without sacrificing the device dimension. Furthermore, the substrate current, which induces a junction breakdown and lateral BJT snapback voltage down, is eliminated due to the formation of the high-voltage MOS on the silicon-on-insulator substrate such that the reliability issue accompanying with high-voltage MOS is improved.

In other words, an N-channel asymmetric high-voltage MOS device comprises a substrate having an insulating layer thereon and a P-type silicon layer on the insulating layer. A plurality of shallow trench isolations defining an active area is formed in the P-type silicon layer. A field oxide layer is thermally formed in the active area of the P-type silicon layer. An N-type drift region is formed under the field oxide layer in the P-type silicon layer. A gate structure including a gate oxide layer and a polysilicon layer is formed on the P-type silicon layer in the active area to cover a portion of the field oxide layer. A lightly doped N-type source region and a lightly doped N-type drain region are formed opposite to each other aside of the gate structure in the P-type silicon layer in the active area, wherein the lightly doped N-type drain region is isolated from the gate structure by the field oxide layer. A heavy doped N-type source region and a heavy doped N-type drain region are spaced-apart formed in the lightly doped N-type source region and the lightly doped N-type drain region respectively. The lightly doped N-type source and drain regions serve as high potential junction barriers and can contact the insulating layer.

Although specific embodiments have been illustrated and described, it will be obvious to those skilled in the art that various modifications may be made without departing from what is intended to be limited solely by the appended claims.

What is claimed is:

1. A high-voltage metal-oxide-semiconductor device comprising:
a substrate having an insulating layer thereon and a semiconductor layer of a first conductive type on the insulating layer;
a plurality of shallow trench isolations defining an active area formed in said semiconductor layer;
a field oxide layer formed in said active area of said semiconductor layer;
a drift region of a second conductive type formed under said field oxide layer in said semiconductor layer;
a gate structure formed on said semiconductor layer in said active area to cover a portion of said field oxide layer;
a first source region of said second conductive type having a first dopant concentration and a first drain region of said second conductive type having said first dopant concentration formed opposite to each other aside of said gate structure in said semiconductor layer in said active area, wherein said first drain region is isolated from said gate structure by said field oxide layer; and
a second source region of said second conductive type having a second dopant concentration and a second drain region of said second conductive type having said second dopant concentration formed in said first source region and said first drain region respectively, wherein said second dopant concentration is higher than said first dopant concentration.

2. The device according to claim 1, wherein said substrate is a silicon-on-insulator substrate.

3. The device according to claim 2, wherein said semiconductor layer is a P-type silicon layer.

4. The device according to claim 3, wherein said drift region with said second conductive type is an N-type drift region.

5. The device according to claim 3, wherein said first source region and said first drain region are a lightly doped N-type source region and a lightly doped N-type drain region.

6. The device according to claim 3, wherein said second source region and said second drain region are a heavy doped N-type source region and a heavy doped N-type drain region.

7. The device according to claim 1, wherein said gate structure comprises a gate dielectric layer and a conductive layer.

8. The device according to claim 1, wherein said first source region and said first drain region contact said insulating layer.

9. A high-voltage metal-oxide-semiconductor device comprising:
a P-type silicon-on-insulator substrate having an insulating layer thereon and a P-type silicon layer on the insulating layer;
a plurality of shallow trench isolations defining an active area formed in said P-type silicon layer;
a field oxide layer formed in said active area of said P-type silicon layer;
an N-type drift region formed under said field oxide layer in said P-type silicon layer;
a gate structure formed on said P-type silicon layer in said active area to cover a portion of said field oxide layer;
a lightly doped N-type source region and a lightly doped N-type drain region formed opposite to each other aside of said gate structure in said P-type silicon layer in said active area, wherein said lightly doped N-type drain region is isolated from said gate structure by said field oxide layer; and
a heavy doped N-type source region and a heavy doped N-type drain region formed in said lightly doped N-type source region and said lightly doped N-type drain region respectively.

10. The device according to claim 9, wherein said gate structure comprises a gate dielectric layer and a conductive layer.

11. The device according to claim 9, wherein said lightly doped N-type source region and said lightly doped N-type drain region contact said insulating layer.

12. A high-voltage metal-oxide-semiconductor device comprising:
an N-type silicon-on-insulator substrate having an insulating layer thereon and an N-type silicon layer on the insulating layer;
a plurality of shallow trench isolations defining an active area formed in said N-type silicon layer;
a field oxide layer formed in said active area of said N-type silicon layer;
a P-type drift region formed under said field oxide layer in said N-type silicon layer;
a gate structure formed on said N-type silicon layer in said active area to cover a portion of said field oxide layer;
a lightly doped P-type source region and a lightly doped P-type drain region formed opposite to each other aside of said gate structure in said N-type silicon layer in said active area, wherein said lightly doped P-type drain region is isolated from said gate structure by said field oxide layer; and
a heavy doped P-type source region and a heavy doped P-type drain region formed in said lightly doped P-type source region and said lightly doped P-type drain region respectively.

13. The device according to claim 12, wherein said gate structure comprises a gate dielectric layer and a conductive layer.

14. The device according to claim 12, wherein said lightly doped P-type source region and said lightly doped P-type drain region contact said insulating layer.
